(19) United States
(12) Patent Application Publication
(10) Pub. No.: US 2024/0215387 A1
(43) Pub. Date: Jun. 27, 2024

(54) Cover Window Assembly and Foldable Display Device

(71) Applicant: LG Display Co., Ltd., Seoul (KR)

(72) Inventors: Seongmin Yang, Paju-si (KR); Euijun Lee, Seoul (KR); Moowook Bang, Paju-si (KR); Kilsu Park, Paju-si (KR); Changryeom Kim, Paju-si (KR); Yuseok Oh, Gimpo-si (KR); Yongsoo Kim, Chilgok-gun (KR); Eungchul Park, Daegu (KR); Panyoul Kim, Paju-si (KR)

(21) Appl. No.: 18/542,312

(22) Filed: Dec. 15, 2023

(30) Foreign Application Priority Data
Dec. 23, 2022 (KR) 10-2022-0182739

(51) Int. Cl. H10K 59/80; C03C 17/34; H10K 102/00

(52) U.S. Cl. CPC H10K 59/872; C03C 17/3405; H10K 59/8792; C03C 2217/90; H10K 2102/311

(57) ABSTRACT

A cover window assembly of embodiments is attached onto a flexible display panel by an optically transparent adhesive, and comprises a cover glass, a primer resin layer directly coated on the cover glass, and a protective layer disposed on the primer resin layer. The primer resin layer may have a greater storage modulus than the optically transparent adhesive.

### CROSS-REFERENCE TO RELATED APPLICATION

This application claims priority to and the benefit of Korean Patent Application No. 10-2022-0182739 filed on Dec. 23, 2022, which is hereby incorporated by reference as if fully set forth herein.

### TECHNICAL FIELD

The present disclosure relates to a cover window assembly and a foldable display device. The present disclosure, in particular, relates to a novel cover window assembly having improved surface hardness and strength and excellent optical properties, and a foldable display device comprising the same.

### BACKGROUND

Display devices displaying an image comprise various types of display devices such as liquid crystal display (LCD) devices, organic light-emitting diode (OLED) display devices, inorganic light-emitting diode (ILED) display devices, quantum dot (QD) display devices, electrophoresis display (EPD) devices, and the like.

In recent years, foldable display devices in which a display panel can be folded or unfolded have been developed to ensure a large screen and mobility.

To protect the display panel of a foldable display device, a flexible cover window is needed. The flexible cover window needs to have high surface hardness for preventing a scratch, high strength for preventing damage, and excellent optical properties for preventing deterioration of image quality of a display device.

### SUMMARY

As a flexible cover window, a structure in which thin tempered glass and a protective film are bonded using an optically transparent adhesive has been developed.

A flexible cover window having the above-described structure has low surface hardness that is about B˜6B of pencil hardness, and low strength of 1 kgf or less. Additionally, in the process of bonding the thin tempered glass and the protective film with the optically transparent adhesive having a low storage modulus, a tangerine peel stain can be caused easily due to the unevenness on the surface of the optically transparent adhesive, resulting in deterioration of optical properties such as a decrease of light transmittance, an increase in Haze and the like.

The applicants of the present disclosure devised a novel flexible cover window assembly having improved surface hardness and strength and excellent optical properties.

The objective of the present disclosure is to provide a novel flexible cover window assembly having improved surface hardness and strength and excellent optical properties, and a foldable display device comprising the same.

Objectives of the present disclosure are not limited to the above ones, and other objectives that are not mentioned above can be clearly understood from the following description by one having ordinary skill in the art.

A cover window assembly of embodiments is attached onto a flexible display panel by an optically transparent adhesive, and comprises a cover glass, a primer resin layer directly coated on the cover glass, and a protective layer disposed on the primer resin layer. The primer resin layer may have a greater storage modulus than the optically transparent adhesive.

A foldable display device of embodiments comprises a flexible display panel, a cover window assembly disposed on the flexible display panel, and an optically transparent adhesive disposed between the flexible display panel and the cover window assembly, and the cover window assembly comprises a cover glass, a primer resin layer directly coated on the cover glass, and a protective layer disposed on the primer resin layer. The primer resin layer may have a greater storage modulus than the optically transparent adhesive, and have a less storage modulus than the protective layer.

Other particulars of embodiments are provided in the detailed description and the drawings.

In the embodiments, the primer resin layer having a greater storage modulus than the optically transparent adhesive is directly coated on the cover glass, and then the protective layer is coated on or attached to the primer resin layer, such that the cover window assembly can have excellent optical properties, i.e., no stain like tangerine peel, light transmittance of 89% or greater, and a haze value of 0.14 or less.

In the embodiment, since the primer resin layer having a greater storage modulus than the optically transparent adhesive is included, the surface hardness and puncture strength of the cover window assembly can be improved.

In the embodiment, since the primer resin layer having a greater storage modulus than the optically transparent adhesive covers the lateral surfaces of the cover glass, an external shock applied to the lateral surfaces of the cover glass can be absorbed, and damage to the lateral surfaces of the cover glass can be prevented.

In the embodiment, since the primer resin layer comprises silane as an additive, the adhesive force of the primer resin layer can be increased, and the resilient properties of the primer resin layer can be improved. Thus, the warpage of the cover window assembly in the folding area can be improved.

In the embodiment, since the lateral surfaces of the protective layer and the lateral surfaces of the primer resin layer protrude further than the lateral surfaces of the display panel, the display panel can be protected from an external shock that is applied in the directions of the lateral surfaces of the display panel.

Aspects according to the present disclosure are not limited to the above ones, and other aspects and advantages that are not mentioned above can be clearly understood from the following description by one having ordinary skill in the art.

### BRIEF DESCRIPTION OF DRAWINGS

The accompanying drawings constitute a part of the specification, illustrate one or more embodiments in the disclosure, and together with the specification, explain the disclosure, wherein:

FIG. 1 is a perspective view showing a foldable display device of one embodiment;

FIG. 2 is a cross-sectional view showing the foldable display device of one embodiment;

FIG. 3 is an enlarged view showing a partial area of FIG. 2;

FIG. 4 is a cross-sectional view schematically showing a display panel of the foldable display device of one embodiment; and

FIGS. 5 and 6 are cross-sectional views showing foldable display devices of embodiments.

### DETAILED DESCRIPTION

Advantages and features in the present disclosure and a method of ensuring the same can be clearly understood from embodiments that are described hereafter with reference to accompanying drawings. The subject matter of the disclosure, however, can be embodied in various different forms, and should not be construed as being limited to the embodiments set forth herein. Rather, the embodiments are provided as examples so that the disclosure can be thorough and complete and can fully convey the scope of the disclosure to one having ordinary skill in the art.

The shapes, sizes, ratios, angles, number and the like of the components illustrated in the drawings provided for describing the embodiments of the disclosure are given only as examples, and the subject matter of the disclosure is not limited by the particulars in the drawings. Throughout the disclosure, like reference numerals denote like components. In describing the subject matter, detailed description of well-known technologies relevant to the disclosure is omitted if it is deemed to make the gist of the disclosure unnecessarily vague. Throughout the disclosure, the terms “comprise”, “have”, “be comprised of” and the like are to imply the inclusion of any other component, but for the term “only”. Further, the singular forms “a”, “an” and “the” are intended to include the plural forms as well, unless explicitly stated otherwise.

In describing a component, the margin of error is to be included, though not explicitly described.

In the disclosure, when spatial terms such as “being on”, “being in an upper portion”, “being in a lower portion”, “being adjacent to” and the like are used to describe a position relationship between two components, one or more additional components can be interposed between the two components unless terms such as “right” or “directly” are used.

The terms “first”, “second” and the like are used herein only to distinguish one component from another component. Thus, the components are not to be limited by the terms. Certainly, a first component mentioned hereafter can be a second component, within the technical spirit of the disclosure. In describing components, terms such as first, second and the like can be used. These terms are only intended to distinguish a component from another component, and the components are not limited by such terms. Accordingly, a first component described below can be a second component within the technical spirit of the disclosure.

Throughout the disclosure, identical reference numerals can denote identical components.

The size and thickness of each component in the drawings are to provide convenience for description, and the size and thickness of each component are not necessarily limited to the size and thickness illustrated in the drawings.

Features of the embodiments of the disclosure can be partially or entirely mixed or combined, and can technically link and operate in various ways, as one having ordinary skill in the art understands sufficiently. Further, each embodiment can be embodied independently, or in connection with each other.

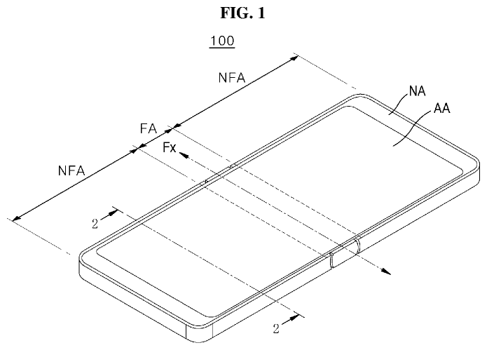

Hereafter, foldable display devices of embodiments are described with reference to the FIG. 1 is a perspective view showing a foldable display device according to an embodiment of the present disclosure.

Referring to FIG. 1, a foldable display device 100 according to an embodiment may comprise a display area (AA), a non-display area NA, a folding area FA, and a non-folding area NFA.

The display area AA may be an area that displays an image. The non-display area NA may be disposed at the edge of the display area AA, and may be an area that does not display an image. The folding area FA may be formed around a folding axis Fx, and may overlap a portion of the display area AA and a portion of the non-display area NA. For example, the folding area FA may be an area that bends with a predetermined radius of curvature, in the case where the foldable display device 100 bends in at least one of an inner folding manner or an outer folding manner. The area except for the folding area FA may be a non-folding area NFA. The non-folding area NFA may overlap a portion of the display area AA and a portion of the non-display area NA.

Additionally, the foldable display device 100 may further comprise a hinge structure for folding a display panel and the like, and a case that supports and accommodates a display panel and the like. The display area AA, the non-display area NA, the folding area FA, and the non-folding area NFA may be applied to components of the foldable display device 100 in the same way or in a similar way.

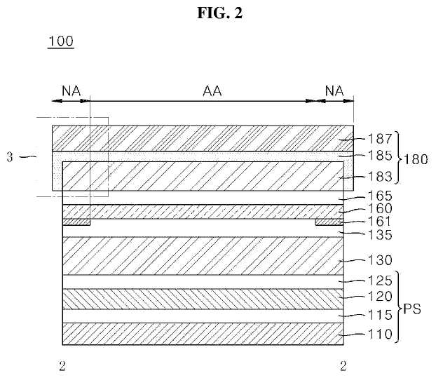

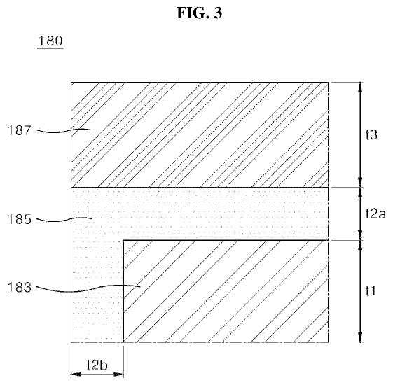

FIG. 2 is a cross-sectional view showing a foldable display device according to an embodiment. FIG. 3 is an enlarged view showing a partial area of FIG. 2.

Referring to FIGS. 2 and 3, a foldable display device 100 according to an embodiment comprises a support structure PS, a display panel 130, a base film 160, a light-shielding layer 161, and a cover window assembly 180. Additionally, the foldable display device 100 may further comprise an adhesive layer 135 disposed between the display panel 130 and the base film 160, and an adhesive layer 165 disposed between the base film 160 and the cover window assembly 180.

The cover window assembly 180 may be disposed on the display panel 130. The cover window assembly 180 may protect the display panel 130 from an external shock, moisture, heat and the like.

The support structure PS may be disposed under the display panel 130, support the display panel 130, and discharge heat generated from the display panel 130 outward.

The cover window assembly 180 may comprise a cover glass 183, a primer resin layer 185, and a protective layer 187.

The cover glass 183 may be made of tempered glass exhibiting shock resistance and light transmittance, to protect the display panel 130. To ensure strength and folding properties, the thickness t1 of the cover glass 185 may range from 30 μm to 120 μm.

In the case of a cover glass 183 made of tempered glass, the cover glass 183 may be broken due to an external shock or stress. At this time, to prevent fragments of the cover glass 183 from being scattered, the protective layer 187 may be disposed on the upper surface of the cover glass 183. The primer resin layer 185 may be disposed between the cover glass 183 and the protective layer 187, thereby the protective layer 187 may be attached to the cover glass 183.

The primer resin layer 185 may be directly coated on the cover glass 183, and the primer resin layer 185 may cover the upper surface and lateral surfaces of the cover glass 183. Additionally, the lateral surfaces of the primer resin layer 185 may protrude further than the lateral surfaces of the display panel 130.

The thickness t2a of the primer resin layer 185 covering the lateral surfaces of the cover glass 183 may be greater than the thickness t2b of the primer resin layer 185 covering the upper surface of the cover glass 183.

The thickness t2a of the primer resin layer 185 covering the upper surface of the cover glass 183 may range from 1 μm to 20 μm, for example. The thickness t2b of the primer resin layer 185 covering the lateral surfaces of the cover glass 183 may range from 10 μm to 300 μm, for example.

The storage modulus of the primer resin layer 185 may be greater than that of an optically transparent adhesive. Additionally, the storage modulus of the primer resin layer 185 may be less than that of the protective layer 187. The primer resin layer 185 may have a storage modulus of 100 MPa to 5 GPa, for example.

The primer resin layer 185 may comprise a urethane, acryl and epoxy-based resin or an elastomer. The primer resin layer 185 may further comprise silane as an additive.

The primer resin layer 185 may be formed by coating a composition comprising 20 to 80 wt % of one or more of epoxy acrylate, urethane acrylate and polyester acrylate as an oligomer, 10 to 50 wt % of one or more of methyl acrylate, ethyl acrylate, butyl acrylate, 2-ethylhexyl acrylate and methyl methacrylate as a monomer, 1 to 5 wt % of one or more of hydroxycyclohexyl phenyl ketone, 2,2-dimethoxy-2-phenyl, acetophenone, benzophenone and phenyl-2-hydoxy-2-propyl ketone as an initiator, and 1 to 15 wt % of silane as an additive.

For example, urethane acrylate may be used as an oligomer, and at least one or two of methyl methacrylate-ethyl acrylate polymer or 2-hydroxyethyl methacrylate may be used as a monomer.

Further, silane selected from at least one or two or more of phenylsilane, phenyltrimethoxysilane, phenyltriethoxysilane, phenylchlorosilane, phenyltrichlorosilane, γ-glycidoxypropyltriphenoxysilane, γ-glycidoxypropylmethyldiphenoxysilane, dichlorodiphenylsilane, n-phenyl-γ-aminopropyltrimethoxysilane, dimethoxymethylphenylsilane, diphenyldimethoxysilane, diethoxydiphenylsilane, methylphenyldiethoxysilane, methylphenyldichlorosilane, and phenoxytrimethylsilane may be used as an additive.

The protective layer 187 may be a resin layer coated directly on the upper surface of the primer resin layer 185 or a polymer film attached directly to the upper surface of the primer resin layer 185. To ensure strength and folding properties, the thickness t3 of the protective layer 187 may range from 10 μm to 100 μm. Additionally, the lateral surfaces of the protective layer 187 may protrude further than the lateral surfaces of the display panel 130. A hard coating layer may be formed on the protective layer 187. The hard coating layer may comprise a colorless organic-inorganic complex material. One or more of an anti-glare layer, an anti-reflection layer and an anti-fingerprint layer may be further formed on the protective layer 187. One or more of the anti-glare layer, the anti-reflection layer, the anti-fingerprint layer and the hard coating layer may be disposed on the protective layer 187.

In the case where the protective layer 187 is a film, the protective layer 187 may comprise polyethylene terephthalate (PET), colorless polyimide (CPI) or a stack of polyethylene terephthalate (PET) and colorless polyimide (CPI) and the like.

Additionally, in the case where the protective layer 187 is a resin layer, the protective layer 187 may comprise an acryl or epoxy-based resin and the like. The protective layer 187 may be formed by coating a composition comprising 20 to 80 wt % of one or more of epoxy acrylate, urethane acrylate, polyester acrylate and a siloxane oligomer as an oligomer, 10 to 50 wt % of one or more of a bisphenol-based epoxy monomer, glycidylether of tetrahydroxyphenylmethane glycidylether of tetrahydroxybenzophenone, or propylene carbonate as a monomer, 1 to 10 wt % of a free radical initiator, or a cationic initiator as an initiator, and 1 to 15 wt % of silane as an additive.

For example, the siloxane oligomer may comprise an alkyl group in which an epoxy group is replaced, and an alkyl group in which one or two or more of a glycidyl group, an alkyl group, an alkenyl group, an alkynyl group, an acrylic group, a metacrylic group and an aryl group are replaced.

For example, the bisphenol-based epoxy monomer comprises at least one or two or more of bisphenol A diglycidyl ether, bisphenol F diglycidyl ether, bisphenol S diglycidyl ether, bisphenol B diglycidyl ether, bisphenol C diglycidyl ether, bisphenol M diglycidyl ether, 1,4-butanediol diglycidyl ether, (chloromethyl)oxirane, and 4,4″-(1-methylethylidene)biscyclohexanol.

In the cationic initiator, at least one or two of a sulfonium salt compound or idonium Hexafluorophosphate may be mixed.

The silane as an additive may comprise one or two or more of phenylsilane, phenyltrimethoxysilane, phenyltriethoxysilane, phenylchlorosilane, phenyltrichlorosilane, γ-glycidoxypropyltriphenoxysilane, γ-glycidoxypropylmethyldiphenoxysilane, dichlorodiphenylsilane, N-phenyl-γ-aminopropyltrimethoxysilane, dimethoxymethylphenylsilane, diphenyldimethoxysilane, diethoxydiphenylsilane, methylphenyldiethoxysilane, methylphenyldichlorosilane, phenoxytrimethylsilane, and 3-glycidoxypropyltrimethoxy silane.

In the embodiment, the primer resin layer 185 having a greater storage modulus, e.g., 100 MPa to 5 GPa, than the optically transparent adhesive is directly coated on the cover glass 183, and then the protective layer 187 is coated on or attached to the primer resin layer 185, such that the cover window assembly 180 has excellent optical properties, i.e., no stain like tangerine peel, light transmittance of 89% or greater, and a haze value of 0.14 or less.

Additionally, in the embodiment, since the primer resin layer 185 having a high storage modulus (e.g., 100 MPa to 5 GPa) is included, the surface hardness and puncture strength of the cover window assembly 180 can be improved, for example.

Further, in the embodiment, since the primer resin layer 185 having a storage modulus of 100 MPa to 5 GPa covers the lateral surfaces of the cover glass 183, an external shock applied to the lateral surfaces of the cover glass 183 can be absorbed, and damage to the lateral surfaces of the cover glass 183 can be prevented.

Further, in the embodiment, since the primer resin layer 185 comprises silane as an additive, the adhesive force of the primer resin layer 185 can be increased, and the resilient properties of the primer resin layer 185 can be improved. Thus, the warpage of the cover window assembly 180 in the folding area can be improved.

Furthermore, in the embodiment, since the lateral surfaces of the protective layer 187 and the lateral surfaces of the primer resin layer 185 protrude further than the lateral surfaces of the display panel 13, the display panel 130 can be protected from an external shock that is applied in the directions of the lateral surfaces of the display panel 130.

The foldable display device 100 of one embodiment may further comprise a base film 160 disposed under the cover widow assembly 180, and a light-shielding layer 161 disposed directly at the edges of the lower surface of the base film 160. The light-shielding layer 161 may be coated based on a printing method using black ink, but not limited. The base film 160 may be attached to the lower surface of the cover glass 183 by the adhesive layer 165. The lower surface of the base film 160, on which the light-shielding layer 161 is disposed, may be attached to the upper surface of the display panel 130 by the adhesive layer 135. The adhesive layers 135, 165 may be transparent, and may be comprised of a pressure sensitive adhesive (PSA) comprising an optically transparent adhesive (OCA) and the like.

In one embodiment, the light-shielding layer 161 may be directly disposed at the edges of the upper surface of the base film 60.

The display panel 130 may display an image. The display panel 130 may be a flexible display panel. For example, the display panel 130 may be an organic light-emitting diode display panel using a flexible substrate, but not limited. The display panel 130 may be an inorganic light-emitting diode display panel, a liquid crystal display panel, an electrophoresis display panel and the like.

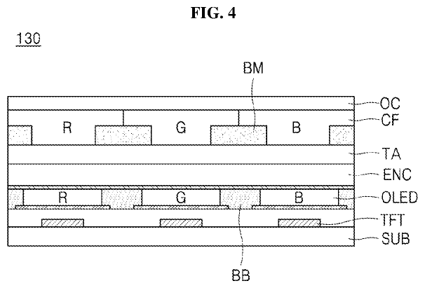

Referring to FIG. 4, in the case where the display panel 130 is an organic light-emitting diode display panel, the display panel 130 may comprise a thin film transistor TFT that is disposed at each sub pixel on a flexible substrate SUB, an organic light-emitting element OLED that is disposed at each sub pixel and connects to the thin film transistor, and an encapsulation layer ENC that covers the organic light-emitting elements OLED to prevent moisture and oxygen from permeating from the outside. For example, in relation to the organic light-emitting elements OLED, each sub pixel may be configured to irradiate red light, green light and blue light, or irradiate white light. Each of the organic light-emitting elements OLED may comprise an anode electrode, an organic light-emitting layer and a cathode electrode. The organic light-emitting elements OLED may be spaced from one another by a bank BB. The bank BB may cover the edge of the anode electrode. The bank BB may be a black bank comprising black pigment or black dye. Additionally, the display panel 130 may further comprise a touch electrode array TA that is formed on the encapsulation layer ENC, color filters R, G, B that are on the touch electrode array TA, a black mattress BM that is disposed among the color filters, and an overcoat layer OC that covers the color filters R, G, B. The black mattress BM may be disposed to overlap the bank BB, and may have a greater with than the bank BB. Touch electrodes of the touch electrode array TA may be disposed to overlap the black mattress BM.

The support structure PS may comprise a back plate 120 and a support plate 110. Additionally, the support structure PS may comprise an adhesive layer 115 that is disposed between the back plate 120 and the support plate 110, and an adhesive layer 125 that is disposed on the back plate 120.

The back plate 120 may be disposed under the display panel 130 and support the display panel 130. The display panel 130 applied to the foldable display device 100 may be very thin and flexible. The back plate 120 may help to improve the rigidity of the display panel 130, prevent foreign substances from adhering to the lower surface of the display panel 130, and buffer a shock applied from the outside. The back plate 120 may be a polymer film. A polymer film that can be used for the back plate 103, for example, may be made of polyimide (PI), polyethylene terephthalate (PET), polycarbonate (PC), and polyethylene naphthalate (PEN), but not limited.

The adhesive layer 125 may be disposed between the back plate 120 and the display panel 130. The back plate 120 may be attached to the lower surface of the display panel 130 by the adhesive layer 125. The adhesive layer 125 may be transparent, and may be comprised of a pressure sensitive adhesive PSA comprising an optically transparent adhesive OCA and the like.

The support plate 110 may help the display panel 130 to be folded or unfolded easily. The support plate 110 may discharge heat generated by the display panel 130 to the outside. The support plate 110 may be attached to the lower surface of the back plate 120 by the adhesive layer 115. The adhesive layer 115 may be transparent, and may be comprised of a pressure sensitive adhesive PSA comprising an optically transparent adhesive OCA and the like.

The support plate 110 may comprise at least one or more of support plates and at least one or more of adhesive layers. The support plate 110 may comprise a first support plate and a second support plate. The support plate 110 may further comprise an adhesive layer that is disposed between the first support plate and the second support plate. The first support plate may be a lower support plate, and the second support plate may be an upper support plate.

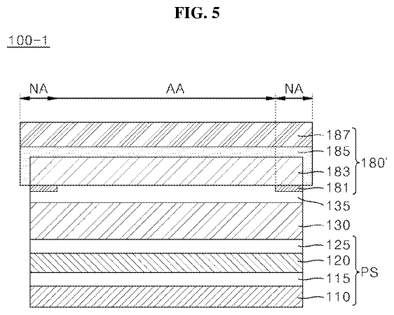

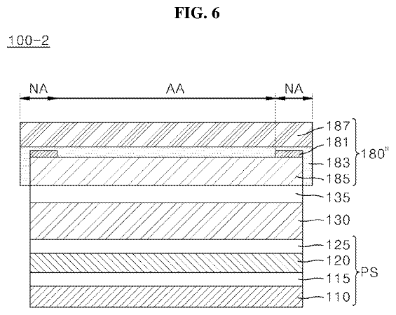

FIGS. 5 and 6 are cross-sectional views showing foldable display devices of embodiments.

Referring to FIG. 5, a foldable display device 100-1 may comprise a light-shielding layer 181 disposed directly at the edges of the lower surface of the cover glass 183, instead of the light-shielding layer 161 disposed at the edges of the lower surface of the base film 160. A cover window assembly 180′ of the foldable display device 100-1 may further comprise the light-shielding layer 181 disposed directly at the edges of the lower surface of the cover glass 183.

Referring to FIG. 6, a foldable display device 100-2 may comprise a light-shielding layer 181 that is directly coated at the edges of the upper surface of the cover glass 183, instead of a light-shielding layer 161 that is disposed at the edges of the lower surface of the base film 160. At this time, the light-shielding layer 181 may be formed at the edges of the upper surface of the cover glass 183, and then the primer resin layer 185 may be formed. A cover window assembly 180″ of the foldable display device 100-2 may further comprise the light-shielding layer 181 disposed directly at the edges of the upper surface of the cove glass 183, and the primer resin layer 185 may cover the light-shielding layer 181.

A cover window assembly and a foldable display device of embodiments are described as follows.

The cover window assembly of embodiments is attached onto a flexible display panel by an optically transparent adhesive, and comprises a cover glass, a primer resin layer directly coated on the cover glass, and a protective layer disposed on the primer resin layer. The primer resin layer may have a greater storage modulus than the optically transparent adhesive.

In several embodiments, the primer resin layer may have a less storage modulus that the protective layer.

In several embodiments, the primer resin layer may have a storage modulus of 100 MPa to 5 GPa.

In several embodiments, the primer resin layer may cover the upper surface and the lateral surfaces of the cover glass.

In several embodiments, the thickness of the primer resin layer covering the lateral surfaces of the cover glass may be greater than the thickness of the primer resin layer covering the upper surface of the cover glass.

In several embodiments, the thickness of the primer resin layer covering the upper surface of the cover glass may range from 1 μm to 20 μm.

In several embodiments, the thickness of the primer resin layer covering the lateral surfaces of the cover glass may range from 10 μm to 300 μm.

In several embodiments, the primer resin layer may comprise a urethane, acryl and epoxy-based resin or an elastomer.

In several embodiments, the primer resin layer may further comprise silane as an additive.

In several embodiments, the protective layer may be a resin layer that is directly coated on the primer rein layer or a film that is directly attached onto the primer resin layer.

In several embodiments, the cover window assembly may further comprise a light-shielding layer that is directly coated at the edges of the lower surface of the cover glass.

In several embodiments, the cover window assembly may further comprise a light-shielding layer that is directly coated at the edges of the upper surface of the cover glass, and the primer resin layer may cover the light-shielding layer.

The foldable display device of embodiments comprises a flexible display panel, a cover window assembly disposed on the flexible display panel, and an optically transparent adhesive disposed between the flexible display panel and the cover window assembly, and the cover window assembly comprises a cover glass, a primer resin layer directly coated on the cover glass, and a protective layer disposed on the primer resin layer. The primer resin layer may have a greater storage modulus than the optically transparent adhesive, and have a less storage modulus that the protective layer.

In several embodiments, the primer resin layer may have a storage modulus of 100 MPa to 5 GPa.

In several embodiments, the lateral surfaces of the protective layer and the lateral surfaces of the primer resin layer may protrude further than lateral surfaces of the display panel.

In several embodiments, the primer resin layer may cover the upper surface and the lateral surfaces of the cover glass.

In several embodiments, the thickness of the primer resin layer covering the lateral surfaces of the cover glass may be greater than the thickness of the primer resin layer covering the upper surface of the cover glass.

In several embodiments, the primer resin layer may comprise a urethane, acryl and epoxy-based resin or an elastomer which contains silane.

In several embodiments, the foldable display device may further comprise a base film disposed under the cover window assembly, and a light-shielding layer directly coated at the edges of the lower surface or the upper surface of the base film.

In several embodiments, the cover window assembly may comprise a light-shielding layer that is directly coated at the edges of the lower surface or the upper surface of the cover glass.

The embodiments of the present disclosure are described above with reference to the accompanying drawings. However, embodiments are not limited to the embodiments set forth herein, and can be modified in various different forms within the technical spirit of the disclosure. It is to be understood that the embodiments set forth herein are provided as examples to describe the technical spirit of the disclosure rather than limiting the technical spirit of the disclosure and are not intended to limit the scope of the technical spirit. The features of the embodiments of the disclosure can be partially or entirely mixed or combined, and can technically link and operate in various ways by one having ordinary skill in the art. Further, each embodiment can be embodied independently, or in connection with each other. The scope of protection of the subject matter is to be interpreted according to following claims, and all the technical spirit within a scope equivalent to the technical scope of the claims is to be construed as being included in the scope of the right to the subject matter of the disclosure.

1. A cover window assembly that is attached onto a flexible display panel by an optically transparent adhesive, the cover window assembly comprising: a cover glass, a primer resin layer coated directly on the cover glass and a protective layer disposed on the primer resin layer,
wherein the primer resin layer has a storage modulus greater than a storage modulus of the optically transparent adhesive.

2. The cover window assembly of claim 1, wherein the primer resin layer has a storage modulus less than a storage modulus of the protective layer.

3. The cover window assembly of claim 1, wherein the primer resin layer has a storage modulus of 100 MPa to 5 GPa.

4. The cover window assembly of claim 1, wherein the primer resin layer covers an upper surface and lateral surfaces of the cover glass.

5. The cover window assembly of claim 4, wherein a thickness of the primer resin layer covering the lateral surfaces of the cover glass is greater than a thickness of the primer resin layer covering the upper surface of the cover glass.

6. The cover window assembly of claim 4, wherein a thickness of the primer resin layer covering the upper surface of the cover glass ranges from 1 μm to 20 μm.

7. The cover window assembly of claim 4, wherein a thickness of the primer resin layer covering the lateral surfaces of the cover glass ranges from 10 μm to 300 μm.

8. The cover window assembly of claim 1, wherein the primer resin layer comprises urethane, acryl, epoxy-based resin or an elastomer.

9. The cover window assembly of claim 8, wherein the primer resin layer further comprises silane as an additive.

10. The cover window assembly of claim 1, wherein the protective layer is a resin layer that is directly coated on the primer resin layer or a film that is attached directly to the primer resin layer.

11. The cover window assembly of claim 1, wherein the cover window assembly further comprises a light-shielding layer that is directly coated at an edge of a lower surface of the cover glass.

12. The cover window assembly of claim 1, wherein the cover window assembly further comprises a light-shielding layer that is directly coated on an edge of an upper surface of the cover glass, and
the primer resin layer covers the light-shielding layer.

13. The cover window assembly of claim 1, wherein one or more of an anti-glare layer, an anti-reflection layer, an anti-fingerprint layer and a hard coating layer are disposed on an upper surface of the protective layer.

14. A foldable display device, comprising:
a flexible display panel;
a cover window assembly disposed on the flexible display panel; and
an optically transparent adhesive disposed between the flexible display panel and the cover window assembly,
wherein the cover window assembly comprises a cover glass, a primer resin layer directly coated on the cover glass, and a protective layer disposed on the primer resin layer, and
the primer resin layer has a storage modulus greater than the optically transparent adhesive, and has a storage modulus less than the protective layer.

15. The foldable display device of claim 14, wherein the primer resin layer has a storage modulus of 100 MPa to 5 GPa.

16. The foldable display device of claim 14, wherein lateral surfaces of the protective layer and lateral surfaces of the primer resin layer protrude further than lateral surfaces of the flexible display panel.

17. The foldable display device of claim 14, wherein the primer resin layer covers an upper surface and lateral surfaces of the cover glass.

18. The foldable display device of claim 14, wherein a thickness of the primer resin layer covering lateral surfaces of the cover glass is greater than a thickness of the primer resin layer covering an upper surface of the cover glass.

19. The foldable display device of claim 14, wherein the primer resin layer comprises urethane, acryl and epoxy-based resin or an elastomer which contains silane.

20. The foldable display device of claim 14, further comprising;
a base film disposed under the cover window assembly; and
a light-shielding layer directly coated at edges of a lower surface or upper surface of the base film.

21. The foldable display device of claim 14, wherein the cover window assembly comprises a light-shielding layer that is directly coated at edges of a lower surface or an upper surface of the cover glass.

22. The foldable display device of claim 14, wherein one or more of an anti-glare layer, an anti-reflection layer, an anti-fingerprint layer and a hard coating layer are disposed on the protective layer.
